(19) United States
(12) Patent Application Publication
(10) Pub. No.: US 2021/0068266 A1
(43) Pub. Date: Mar. 4, 2021

(54) GLASS WIRING SUBSTRATE AND COMPONENT-MOUNTED GLASS WIRING SUBSTRATE

(71) Applicants: SONY CORPORATION, TOKYO (JP); SONY SEMICONDUCTOR SOLUTIONS CORPORATION, KANAGAWA (JP)

(72) Inventors: Hiroshi ISOBE, KANAGAWA (JP); Daisuke MIZUTA, TOKYO (JP)

(21) Appl. No.: 17/040,361

(22) PCT Filed: Mar. 13, 2019
(86) PCT No.: PCT/JP2019/010282

§ 371 Date: Sep. 22, 2020

(30) Foreign Application Priority Data
Mar. 30, 2018 (JP) 2018-066947

(51) Int. Cl. H05K 3/40; H05K 3/28; H05K 3/42

(52) U.S. Cl. CPC H05K 3/4061; H05K 2203/054; H05K 3/428; H05K 3/28

(57) ABSTRACT

A glass wiring substrate includes: a glass substrate 10 including a first surface 10A and a second surface 10B, having a first wiring portion 20 formed on a first surface side, and having a second wiring portion 30 formed on a second surface side; a through hole 40 formed in a region of the glass substrate 10 in which neither the first wiring portion 20 nor the second wiring portion 30 is formed; and a through hole portion 42 formed on an inner wall 41 of the through hole 40, having one end extending to the first wiring portion 20, having another end extending to the second wiring portion 30, and including a hollow portion 43 corresponding to a central portion of the through hole 40, in which a filling member 61 blocking at least a part of the through hole 40 is provided on a region 10C surrounding an edge portion of the through hole 40 of the first surface 10A, and the filling member 61 includes a glass material.

### TECHNICAL FIELD

The present disclosure relates to a glass wiring substrate and a component-mounted glass wiring substrate.

### BACKGROUND ART

In a conventional printed wiring substrate, a first wiring portion formed on a first surface of the printed wiring substrate and a second wiring portion formed on a second surface of the printed wiring substrate facing the first surface are connected via a through hole portion.

On the other hand, there is a known display apparatus substrate disclosed in, for example, Japanese Patent Application Laid-open No. 2009-037164, in which a wiring portion is formed only on one surface of a glass substrate and a plurality of light-emitting elements, specifically, a plurality of light-emitting diodes (LEDs) is mounted on the wiring portion. In such a display apparatus substrate, high integration of the wiring portion is achieved by miniaturization of the wiring portion. Specifically, a wiring pitch of 30 μm is achieved in this patent publication document. In addition, the wiring portion is connected to an external circuit in a so-called frame portion of the display apparatus. However, in such a structure, there is a case where manufacture of a display apparatus having a narrow frame may be subject to some constraints, and application to a tiled display apparatus formed by arraying a plurality of display apparatus substrates may be difficult.

There is a known structure disclosed in, for example, Japanese Patent Laid-Open No. 2016-167491, in which a first wiring portion is formed on a first surface of a glass substrate constituting a display apparatus substrate, a second wiring portion is formed on a second surface of the glass substrate facing the first surface, and the first wiring portion and the second wiring portion are connected via a through hole portion provided in the glass substrate.

### CITATION LIST

### Patent Document

Patent Document 1: Japanese Patent Application Laid-Open No. 2009-037164

Patent Document 2: Japanese Patent Application Laid-Open No. 2016-167491

### SUMMARY OF THE INVENTION

### Problems to be Solved by the Invention

By the way, a glass substrate constituting a display apparatus substrate is heated to two hundred and several tens of degrees Celsius (for example, about 260° C.) in a manufacturing step of the display apparatus substrate (e.g., reflow soldering step). At this time, due to a difference between a linear expansion coefficient of the glass substrate and a linear expansion coefficient of a material constituting a first wiring portion or a second wiring portion (specifically, copper), there may be a problem that stress is applied to the glass substrate and the glass substrate is damaged. In particular, a region of the glass substrate including a through hole portion is likely to be damaged due to microcracks generated in the glass substrate at the time of forming a through hole for the through hole portion.

Therefore, the present disclosure is directed to providing: a glass wiring substrate having a configuration and a structure in which particularly a region in a vicinity of a through hole portion of a glass substrate is hardly damaged; and a component-mounted glass wiring substrate including the glass wiring substrate.

### Solutions to Problems

A glass wiring substrate according to a first aspect and a second aspect of the present disclosure to achieve the above-described object includes:

a glass substrate including a first surface and a second surface facing the first surface, having a first wiring portion formed on a first surface side, and having a second wiring portion formed on a second surface side;

a through hole formed in a region of the glass substrate in which neither the first wiring portion nor the second wiring portion is formed; and

a through hole portion formed on an inner wall of the through hole, having one end extending to the first wiring portion, having another end extending to the second wiring portion, and including a hollow portion corresponding to a central portion of the through hole, in which

a filling member that blocks at least a part of the through hole is provided on a region surrounding an edge portion of the through hole of the first surface.

In addition, in the glass wiring substrate according to the first aspect of the present disclosure, the filling member includes a glass material, and in the glass wiring substrate according to the second aspect of the present disclosure, when a linear expansion coefficient of the glass substrate is defined as CTE₁ and a linear expansion coefficient of the filling member is defined as CTE₂,

0.01≤CTE₂/CTE₁≤5

is satisfied.

A component-mounted glass wiring substrate of the present disclosure to achieve the above-described object includes:

a glass substrate including a first surface and a second surface facing the first surface, having a first wiring portion formed on a first surface side, and having a second wiring portion formed on a second surface side;

a through hole formed in a region of the glass substrate in which neither the first wiring portion nor the second wiring portion is formed;

a through hole portion formed on an inner wall of the through hole, having one end extending to the first wiring portion, having another end extending to the second wiring portion, and including a hollow portion corresponding to a central portion of the through hole; and

an electronic component mounted on at least one of the first wiring portion or the second wiring portion, in which

a filling member that blocks at least a part of the through hole is provided on a region surrounding an edge portion of the through hole of the first surface,

the filling member includes a glass material, or

when a linear expansion coefficient of the glass substrate is defined CTE₁ and a linear expansion coefficient of the filling member is defined as CTE₂,

0.01≤CTE₂/CTE₁≤5

is satisfied.

### BRIEF DESCRIPTION OF DRAWINGS

FIG. 1 is a schematic partial end surface view of a glass wiring substrate, a component-mounted glass wiring substrate, and a display apparatus substrate according to Example 1.

FIGS. 2A, 2B, and 2C are schematic partial end surface views of a vicinity of a through hole portion in a glass wiring substrate, a component-mounted glass wiring substrate, and a display apparatus substrate according to Example 2, a modified example of Example 2, and another modified example of Example 2, respectively.

FIGS. 3A and 3B are schematic partial end surface views of a light-emitting element (light-emitting diode) according to Example 1.

FIGS. 4A and 4B are conceptual views each illustrating a cross-section of a light-emitting element and the like to describe a method of mounting the light-emitting element in Example 1.

FIGS. 5A and 5B are conceptual views each illustrating a cross-section of the light-emitting element and the like to describe the method of mounting the light-emitting element in Example 1, subsequently to FIG. 4B.

FIGS. 6A and 6B are conceptual views each illustrating a cross-section of the light-emitting element and the like to describe the method of mounting the light-emitting element in Example 1, subsequently to FIG. 5B.

FIGS. 7A and 7B are conceptual views each illustrating a cross-section of the light-emitting element and the like to describe the method of mounting the light-emitting element in Example 1, subsequently to FIG. 6B.

FIGS. 8A and 8B are schematic partial end surface views of a vicinity of a through hole portion in Comparative Example 1A and Comparative Example 1B, respectively.

### MODE FOR CARRYING OUT THE INVENTION

In the following, the present disclosure will be described on the basis of Examples with reference to the drawings, but note that the present disclosure is not limited to such Examples, and various values and various kinds of materials in Examples are just examples. Note that a description will be provided in the following order.

1. General Description of Glass Wiring Substrate and Component-Mounted Glass Wiring Substrate according to First Aspect and Second Aspect of Present Disclosure

2. Example 1 (Glass Wiring Substrate and Component-Mounted Glass Wiring Substrate according to First Aspect and Second Aspect of Present Disclosure) 3. Example 2 (Modification of Example 1) 4. Others

<General Description of Glass Wiring Substrate and Component-Mounted Glass Wiring Substrate according to First Aspect and Second Aspect of Present Disclosure>

In a component-mounted glass wiring substrate of the present disclosure,

electronic components can include a light-emitting element and a driving semiconductor device that drives the light-emitting element,

the light-emitting element can be mounted on one wiring portion of the first wiring portion or the second wiring portion, and

the driving semiconductor device can be mounted on the other wiring portion of the first wiring portion or the second wiring portion. Alternatively, the light-emitting element and the driving semiconductor device can be mounted on one or the other wiring portion of the first wiring portion or the second wiring portion.

A display apparatus substrate, to which the component-mounted glass wiring substrate of the present disclosure including the above-described preferable embodiment is applied, includes:

a glass substrate including a first surface and a second surface facing the first surface, having a first wiring portion formed on a first surface side, and having a second wiring portion formed on a second surface side;

a through hole formed in a region of the glass substrate in which neither the first wiring portion nor the second wiring portion is formed;

a through hole portion formed on an inner wall of the through hole, having one end extending to the first wiring portion, having the other end extending to the second wiring portion, and including a hollow portion corresponding to a central portion of the through hole; and

an electronic component mounted on at least one of the first wiring portion or the second wiring portion in which

the electronic component includes at least a light-emitting element, and

a filling member that blocks at least a part of the through hole is provided on a region surrounding an edge portion of the through hole of the first surface.

In addition, in such a display apparatus substrate,

the electronic component includes a light-emitting element and a driving semiconductor device that drives the light-emitting element,

the light-emitting element can be mounted on a light-emitting element attaching portion provided in one wiring portion of the first wiring portion or the second wiring portion, and

the driving semiconductor device can be mounted on a driving semiconductor device attaching portion provided in the other wiring portion of the first wiring portion or the second wiring portion. Alternatively, the light-emitting element and the driving semiconductor device can be mounted on the light-emitting element attaching portion and the driving semiconductor device attaching portion which are provided on one or the other wiring portion of the first wiring portion and the second wiring portion.

A method of manufacturing a glass wiring substrate, which is adapted to manufacture a component-mounted glass wiring substrate of the present disclosure, includes respective steps of:

preparing a glass substrate including a first surface and a second surface facing the first surface;

forming a through hole in a desired region of the glass substrate;

subsequently, forming first wiring on the first surface of the glass substrate, forming second wiring on the second surface of the glass substrate, forming a through hole portion which extends from a first wiring portion and a second wiring portion, is formed on an inner wall of the through hole, and includes a hollow portion corresponding to a central portion of the through hole; and thereafter,

providing, on a region surrounding an edge portion of the through hole of the first surface, a filling member that blocks at least a part of the through hole, in which

the filling member includes a glass material, or

when a linear expansion coefficient of the glass substrate is defined as CTE₁ and a linear expansion coefficient of the filling member is defined as CTE₂,

0.01≤CTE₂/CTE₁≤5

is satisfied.

There is a case where the glass wiring substrate according to the first aspect and the second aspect of the present disclosure, the glass wiring substrate according to the first aspect and the second aspect of the present disclosure constituting the component-mounted glass wiring substrate of the present disclosure, the glass wiring substrate according to the first aspect and the second aspect of the present disclosure constituting the display apparatus substrate, and the glass wiring substrate according to the first aspect and the second aspect of the present disclosure obtained by the method of manufacturing the glass wiring substrate will be collectively referred to as “glass wiring substrate and the like of the present disclosure”. Furthermore, there is a case where the glass wiring substrate according to the first aspect of the present disclosure, the glass wiring substrate according to the first aspect of the present disclosure constituting the component-mounted glass wiring substrate of the present disclosure, the glass wiring substrate according to the first aspect of the present disclosure constituting the display apparatus substrate, and the glass wiring substrate according to the first aspect of the present disclosure obtained by the method of manufacturing the glass wiring substrate will be collectively referred to as “glass wiring substrate and the like according to the first aspect of the present disclosure”.

In the glass wiring substrate and the like of the present disclosure, the filling member can extend through the inside of the through hole, and furthermore, the filling member can extend from the inside of the through hole onto a region surrounding an edge portion of the through hole of the second surface. Alternatively, in the glass wiring substrate and the like of the present disclosure, a second filling member including a glass material and blocking the through hole can be provided on the region surrounding the edge portion of the through hole of the second surface.

In the glass wiring substrate and the like according to the first aspect of the present disclosure including the above-described preferred embodiments and configurations, when the linear expansion coefficient of the glass substrate is defined as CTE₁ and the linear expansion coefficient of the filling member is defined as CTE₂,

0.01≤CTE₂/CTE₁≤5

can be satisfied.

Furthermore, in the glass wiring substrate and the like of the present disclosure including the above-described preferred embodiments and configurations, when a Young's modulus of the glass substrate is defined as E₁ and a Young's modulus of the filling member is defined as E₂,

0.1≤E₂/E₁≤10

can be satisfied.

In the display apparatus substrate, one pixel can include a light-emitting element unit that includes a plurality of light-emitting elements, and when the number of the plurality of light-emitting elements constituting one pixel is defined as “N”, a value of N can be 3 or more. An upper limit of the value of the number of light-emitting elements connected to one driving semiconductor device is not particularly limited as far as the driving semiconductor device can appropriately drive the light-emitting elements. Furthermore, when the number of light-emitting element units (total number of pixels) is defined as U₀, a relation of [total number of light-emitting elements (total number of subpixels)=U₀×N] is established.

The number, a type, mounting (arrangement), an interval, and the like of light-emitting elements constituting the light-emitting element unit are determined in accordance with, for example: a use and a function of a display apparatus including the display apparatus substrate (light-emitting element display apparatus); and specifications required in the display apparatus. In a case of a display apparatus for color display, one pixel (one pixel) in the display apparatus includes a combination (light-emitting element unit) of, for example, a red light-emitting element (red light-emitting subpixel), a green light-emitting element (green light-emitting subpixel), and a blue light-emitting element (blue light-emitting subpixel). Furthermore, a subpixel includes each light-emitting element. In addition, a plurality of light-emitting element units is arrayed in a two-dimensional matrix form in a first direction and a second direction orthogonal to the first direction. When the number of red light-emitting elements constituting the light-emitting element unit is defined as N_{R}, the number of green light-emitting elements constituting the light-emitting element unit is defined as N_{G}, and the number of blue light-emitting elements constituting the light-emitting element unit is defined as N_{B}, N_{R} can be an integer of 1 or 2 or more, N_{G} can be an integer of 1 or 2 or more, and N_{B} can be an integer of 1 or 2 or more. The values of N_{R}, N_{G}, and N_{B} may be equal or may be different. In a case where each of the values of N_{R}, N_{G}, and N_{B} is an integer of 2 or more, the light-emitting elements may be connected in series or may be connected in parallel in one light-emitting element unit. A combination of the values of (N_{R}, N_{G}, N_{B}) is not limited, but (1,1,1), (1,2,1), (2,2,2), and (2,4,2) can be exemplified. In a case where one pixel includes three kinds of subpixels, exemplary arrays of the three kinds of subpixels can include a delta array, a stripe array, a diagonal array, and a rectangle array. In addition, it is only required to drive the light-emitting elements at constant current on the basis of a PWM driving method. Alternatively, three panels can be prepared, a first panel can include a light-emitting portion including the red light-emitting element, a second panel can include a light-emitting portion including the green light-emitting element, and a third panel can include a light-emitting portion including the blue light-emitting element, and thereby light from these three panels can be applied to a projector that collects the light by using, for example, a dichroic prism.

In the method of manufacturing the glass wiring substrate, the first wiring layer, the second wiring layer, and the through hole portion can be formed on the basis of a combination of an electroless plating process, an electrolytic plating process, and an etching process, more specifically, for example, a combination of an electroless copper plating process, an electrolytic copper plating process, and the etching process, and also can be formed on the basis of a combination of a PVD process, the electrolytic plating process, and the etching process. However, the formation of the through hole portion, the first wiring portion, and the second wiring portion is not limited to these processes, and it is also possible to adopt a combination of the PVD process such as a sputtering process or a vacuum deposition process, and the etching process. Alternatively, the first wiring portion or the second wiring portion can be formed on the first surface or the second surface of the glass substrate by: forming a metal layer (including an alloy layer) on the basis of the physical vapor deposition process (PVD process) on the first surface or the second surface of the glass substrate; and then patterning the metal layer, and the through hole portion and the second wiring portion or the first wiring portion can be formed on the basis of a plating process.

The first wiring portion may be provided in one layer, or may be provided in a plurality of layers such as two or more layers. That is, the first wiring portion may have a single-layer wiring structure or a multi-layer wiring structure. The second wiring portion may also be provided in one layer, or may be provided in a plurality of layers including two or more layers. That is, the second wiring portion may also have a single-layer wiring structure or a multi-layer wiring structure.

In the glass wiring substrate and the like of the present disclosure including the above-described various preferred embodiments and configurations, high strain point glass, soda glass (Na₂O.CaO.SiO₂), borosilicate glass (Na₂O.B₂O₃.SiO₂), forsterite (2MgO.SiO₂), and lead glass (Na₂O.PbO.SiO₂) can be exemplified as the glass substrate. As a thickness of the glass substrate, for example, 0.1 mm to 1.1 mm can be exemplified.

The through hole in the glass substrate can be formed by using, for example, a laser. Specifically, for example, the through hole can be formed in the glass substrate on the basis of trepanning using a laser. Furthermore, the through hole having a tapered shape or a stepped shape can be formed by using the laser. Alternatively, the through hole can be formed by drilling, or the through hole can be formed by adopting sandblasting. Alternatively, it is possible to adopt a combination of these machining methods and the etching process.

As a method of mounting the light-emitting element on the light-emitting element attaching portion, the plating process can be exemplified, but not limited to thereto, and it is possible to exemplify other methods, for example, a reflow soldering process and a process using a solder ball or a solder bump. Furthermore, as a method of mounting the driving semiconductor device on the driving semiconductor device attaching portion, the reflow soldering process can be exemplified, but not limited thereto, and it is also possible to exemplify other methods, for example, the plating process or the process using a solder ball or a solder bump.

In the glass wiring substrate and the like of the present disclosure including the above-described various preferred embodiments and configurations, the light-emitting element can include a light-emitting diode (LED), but not limited thereto, and the light-emitting element can include other components such as a semiconductor laser element or the like. In a case where the light-emitting diode or the semiconductor laser element constitute the light-emitting element, a size of the light-emitting element (e.g., a chip size) is not particularly limited, but typically, the size is minute, specifically, for example, 1 mm or less, or for example, 0.3 mm or less, or for example, 0.1 mm or less, or more specifically, 0.03 mm or less. As a material constituting light-emitting layers of the red light-emitting element that emits red light, the green light-emitting element that emits green light, and the blue light-emitting element that emits blue light, it is possible to exemplify a material using a III-V group compound semiconductor, for example, and furthermore, as an example of a material constituting the light-emitting layer of the red light-emitting element, it is also possible to exemplify a material using an AlGaInP-based compound semiconductor, for example. Examples of the III-V group compound semiconductor can include, for example, a GaN-based compound semiconductor (including an AlGaN mixed crystal or an AlGaInN mixed crystal, and a GaInN mixed crystal), a GaInNAs-based compound semiconductor (including a GalnAs mixed crystal or a GaNAs mixed crystal), an AlGaInP-based compound semiconductor, an AlAs-based compound semiconductor, an AlGaInAs-based compound semiconductor, an AlGaAs-based compound semiconductor, a GalnAs-based compound semiconductor, a GaInAsP-based compound semiconductor, a GaInP-based compound semiconductor, a GaP-based compound semiconductor, an InP-based compound semiconductor, an InN-based compound semiconductor, and an AlN-based compound semiconductor.

The light-emitting layer has a laminated structure including a first compound semiconductor layer having a first conductivity type, an active layer, and a second compound semiconductor layer having a second conductivity type different from the first conductivity type. Note that, in a case where the first conductivity type is an n-type, the second conductivity type is a p-type, and in a case where the first conductivity type is the p-type, the second conductivity type is the n-type. Examples of n-type impurities to be added to a compound semiconductor layer can include, for example, silicon (Si), selenium (Se), germanium (Ge), tin (Sn), carbon (C), and titanium (Ti), and examples of p-type impurities can include zinc (Zn), magnesium (Mg), beryllium (Be), cadmium (Cd), calcium (Ca), barium (Ba), and oxygen (O). The active layer may include a single compound semiconductor layer, or may have a single quantum well structure (SQW structure) or a multiple quantum well structure (MQW structure). Examples of a method of forming (depositing) various kinds of compound semiconductor layers including the active layer can include a metal-organic chemical vapor deposition process (MOCVD process, MOVPE process), a metal-organic molecular beam epitaxy process (MOMBE process), a hydride vapor phase epitaxy process (HVPE process) in which halogen contributes to transport or reaction, a plasma-assisted physical vapor deposition process (PPD process), an atomic layer deposition process (ALD process, atomic layer deposition process), and a migration-enhanced. epitaxy process (MEE process). It is only required to select, as appropriate, the above-described compound semiconductors and compositions thereof in order to manufacture the red light-emitting element, the green light-emitting element, and the blue light-emitting element.

In a case where the first conductivity type is the n-type and the second conductivity type is the p-type, a first electrode is an n-side electrode and a second electrode is a p-side electrode. On the other hand, in a case where the first conductivity type is the p-type and the second conductivity type is the n-type, the first electrode is the p-side electrode and the second electrode is the n-side electrode. Here, examples of the p-side electrode can include Au/AuZn, Au/Pt/Ti(/Au)/AuZn, Au/Pt/TiW(/Ti) (/Au)/AuZn, Au/AuPd, Au/Pt/Ti(/Au)/AuPd, Au/Pt/TiW(/Ti) (/Au)/AuPd, Au/Pt/Ti, Au/Pt/TiW(/Ti), Au/Pt/TiW/Pd/TiW(/Ti), Ti/Cu, Pt, Ni, Ag, and Ge. Furthermore, examples of the n-side electrode can include Au/Ni/AuGe, Au/Pt/Ti(/Au)/Ni/AuGe, AuGe/Pd, Au/Pt/TiW(/Ti)/Ni/AuGe, and Ti. Note that a layer specified before “/” is located electrically more distant from the active layer. Alternatively, the second electrode can include a transparent conductive material such as ITO, IZO, ZnO:Al, and ZnO:B. In a case where a layer including the transparent conductive material is used as a current diffusion layer and the second electrode is the n-side electrode, a metal laminated structure exemplified in the case where the second electrode is the p-side electrode may be combined. A first pad portion may be formed on (a surface of) the first electrode, and a second pad portion may be formed on (a surface of) the second electrode. It is desirable that each pad portion have a single layer configuration or a multi-layer configuration including at least one kind of metal selected from a group including Ti (titanium), aluminum (Al), Pt (platinum), Au (gold), and Ni (nickel). Alternatively, each pad portion can have a multi-layer configuration exemplified by a multi-layer configuration of Ti/Pt/Au and a multi-layer configuration of Ti/Au.

As a light-emitting element manufacturing substrate to manufacture the light-emitting element, it is possible to exemplify a GaAs substrate, a GaP substrate, an AIN substrate, an AlP substrate, an InN substrate, an InP substrate, an AlGaInN substrate, an AlGaN substrate, an AlInN substrate, a GaInN substrate, an AlGaInP substrate, an AlGaP substrate, an AlInP substrate, a GaInP substrate, a ZnS substrate, a sapphire substrate, a SiC substrate, an alumina substrate, a ZnO substrate, a LiMgO substrate, a LiGaO₂ substrate, a MgAl₂0₄ substrate, a Si substrate, a Ge substrate, and a substrate on which an underlayer or a buffer layer is formed on a surface (main surface) of these substrates. Note that it is only required to make a selection from these substrates as appropriate to manufacture the red light-emitting element, the green light-emitting element, and the blue light-emitting element.

In each light-emitting element, a light-shielding film may be formed in a desired region of the light-emitting element such that an undesired region is not irradiated with light emitted from the light-emitting element. Examples of a material constituting the light-shielding film can include a material capable of shielding the light, such as titanium (Ti), chromium (Cr), tungsten (W), tantalum (Ta), aluminum (Al), MoSi₂, and the like.

As the light-emitting elements constituting the light-emitting element unit, a fourth light-emitting element, a fifth light-emitting element, . . . may be further added to a first light-emitting element, a second light-emitting element, and a third light-emitting element. As such examples, it is possible to exemplify: a light-emitting element unit to which a subpixel that emits white light is added in order to improve, for example, luminance; a light-emitting element unit to which a subpixel that emits complementary color light is added in order to enlarge a color reproduction range; a light-emitting element unit to which a subpixel that emits yellow light is added in order to enlarge the color reproduction range; and a light-emitting element unit to which a subpixel that emits yellow light and cyan light is added in order to enlarge the color reproduction range.

It is possible to achieve a tiled display apparatus substrate and a display apparatus (light-emitting element display apparatus) each formed by arraying a plurality of component-mounted glass wiring substrates (display apparatus substrates). Alternatively, the component-mounted glass wiring substrate (display apparatus substrate) can be applied to a backlight, a lighting apparatus, an advertisement medium, and the like using light-emitting diodes.

The display apparatus (light-emitting element display apparatus) can be not only a flat type/direct view type image display apparatus of color display represented by a television receiver and a computer terminal but also an image display apparatus that projects an image on a retina of a human being, and a projection type image display apparatus. Note that, in these image display apparatuses, it is only required to adopt a field sequential driving method whereby an image is displayed by controlling, for example, light emission/non-light emission states of each of the first light-emitting element, the second light-emitting element, and the third light-emitting element in a time-sharing manner, but not limited to thereto.

### EXAMPLE 1

Example 1 relates to the glass wiring substrate and the component-mounted glass wiring substrate of the present disclosure according to the first aspect and the second aspect of the present disclosure.

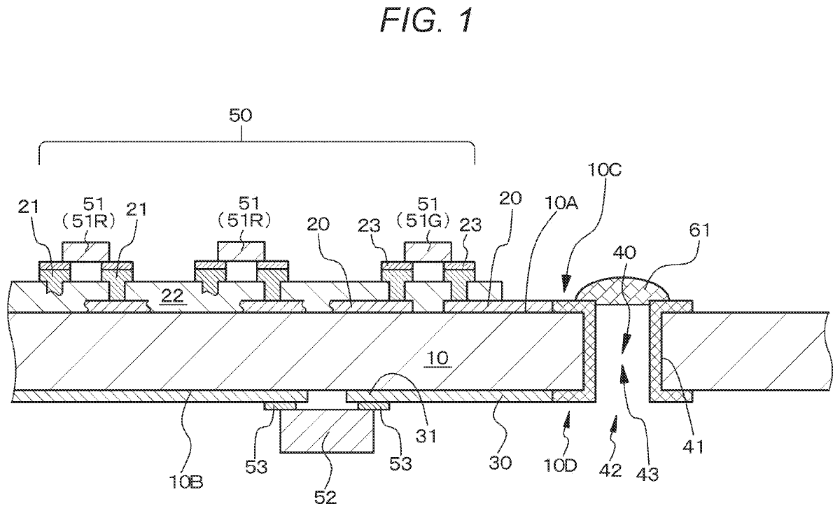

As illustrated in a schematic partial end surface view of FIG. 1, the glass wiring substrate, the component-mounted glass wiring substrate, or the display apparatus substrate of Example 1 includes:

a glass substrate 10 including a first surface 10A and a second surface 10B facing the first surface 10A, having a first wiring portion 20 formed on a first surface side, and having a second wiring portion 30 formed on a second surface side;

a through hole 40 formed in a region of the glass substrate 10 in which neither the first wiring portion 20 nor the second wiring portion 30 is formed; and

a through hole portion 42 formed on an inner wall 41 of the through hole 40, having one end extending to the first wiring portion 20, having the other end extending to the second wiring portion 30, and including a hollow portion 43 corresponding to a central portion of the through hole 40, in which

a filling member 61 that blocks at least a part of the through hole 40 (an upper end portion of the through hole 40 in the example illustrated. The similar is applied to the following description of Example 1) is provided on a region 10C surrounding an edge portion of the through hole 40 of the first surface 10A.

In addition, the filling member 61 includes a glass material, or alternatively, when a linear expansion coefficient of the glass substrate 10 is defined as CTE₁ and a linear expansion coefficient of the filling member 61 is defined as CTE₂,

0.01≤CTE₂/CTE₁≤5

is satisfied.

Furthermore, the component-mounted glass wiring substrate of Example 1 includes:

the glass substrate 10 including the first surface 10A and the second surface 10B facing the first surface 10A, having the first wiring portion 20 formed on the first surface side, and having the second wiring portion 30 formed on the second surface side;

the through hole 40 formed in the region of the glass substrate 10 in which neither the first wiring portion 20 nor the second wiring portion 30 is formed;

the through hole portion 42 formed on the inner wall 41 of the through hole 40, having one end extending to the first wiring portion 20, having the other end extending to the second wiring portion 30, and including the hollow portion 43 corresponding to the central portion of the through hole 40; and

an electronic component mounted on at least one of the first wiring portion 20 or the second wiring portion 30, in which

the filling member 61 that blocks at least a part of the through hole 40 is provided on the region 10C surrounding the edge portion of the through hole 40 of the first surface 10A,

the filling member 61 includes a glass material, or

when the linear expansion coefficient of the glass substrate 10 is defined as CTE₁ and the linear expansion coefficient of the filling member 61 is defined as CTE₂,

0.01≤CTE₂/CTE₁≤5

is satisfied.

Moreover, the display apparatus substrate, to which the component-mounted glass wiring substrate of Example 1 is applied, includes:

the glass substrate 10 including the first surface 10A and the second surface 10B facing the first surface 10A, having the first wiring portion 20 formed on the first surface side, and having the second wiring portion 30 formed on the second surface side;

the through hole 40 formed in the region of the glass substrate 10 in which neither the first wiring portion 20 nor the second wiring portion 30 is formed;

the through hole portion 42 formed on the inner wall 41 of the through hole 40, having one end extending to the first wiring portion 20, having the other end extending to the second wiring portion 30, and including the hollow portion 43 corresponding to the central portion of the through hole 40; and

an electronic component mounted on at least one of the first wiring portion 20 or the second wiring portion 30, in which

the electronic component includes at least a light-emitting element,

the filling member 61 that blocks at least a part of the through hole 40 is provided on the region surrounding the edge portion of the through hole 40 of the first surface 10A,

the filling member 61 includes a glass material, or

when the linear expansion coefficient of the glass substrate 10 is defined as CTE₁ and the linear expansion coefficient of the filling member 61 is defined as CTE₂,

0.01≤CTE₂/CTE₁≤5

is satisfied.

Here, in Example 1, the filling member 61 is provided on the first surface side and blocks a part of the through hole 40 in the illustrated example. However, not limited thereto, the filling member 61 may be provided on the second surface side. The first wiring portion 20, the second wiring portion 30, and the through hole portion 42 include the same material (specifically, copper). A value of the linear expansion coefficient CTE₁ of the glass substrate 10 having a thickness of 0.1 mm to 1.0 mm, a value of the linear expansion coefficient CTE₂ of the filling member 61 including the glass material, and a value of a linear expansion coefficient CTE₃ of the copper constituting the first wiring portion 20, the second wiring portion 30, and the through hole portion 42 are as follows.

Furthermore, when a Young's modulus of the glass substrate 10 is defined as E₁ and a Young's modulus of the filling member 61 is defined as E₂,

0.1≤E₂/E₁≤10

is satisfied. Values of E₁ and E₂ are exemplified below. Moreover, values of a linear expansion coefficient CTE₄ and a Young's modulus E₄ of a solder resist material as described later are exemplified below.

CTE₁: 3.17×10⁻⁶/K

CTE₂: 10×10⁻⁶/K

CTE₃: 17.4×10⁻⁶/K

CTE₄: 16×10⁻⁶/K

E₁: 73.6 GPa

E₂: 40 GPa

E₃: 130 GPa

E₄: 11 GPa

Furthermore, in the component-mounted glass wiring substrate or the display apparatus substrate of Example 1,

the electronic components include a light-emitting element (specifically, a light-emitting diode (LED)) 51 and a driving semiconductor device 52 that drives the light-emitting elements 51,

the light-emitting element 51 is mounted on one wiring portion of the first wiring portion 20 or the second wiring portion 30 (specifically, the first wiring portion 20 in Example 1), and

the driving semiconductor device 52 is mounted on the other wiring portion of the first wiring portion 20 or the second wiring portion 30 (specifically, the first wiring portion 20 in Example 1).

The light-emitting element 51 may be mounted on the second wiring portion 30, and the driving semiconductor device 52 may be mounted on the first wiring portion 20.

Various other electronic components are mounted on the first wiring portion 20 and the second wiring portion 30, but illustration thereof is omitted. The light-emitting elements 51 is connected to the driving semiconductor device 52 via a light-emitting element attaching portions 21 provided on one wiring portion (specifically, the first wiring portion 20 in Example 1), the first wiring portion 20, the through hole portion 42, the second wiring portion 30, a driving semiconductor device attaching portion 31 provided on the other wiring portion (specifically, the second wiring portion 30 in Example 1), and an attaching terminal portion 53. The light-emitting element attaching portions 21 is provided on an insulation layer 22 formed on the first surface 10A of the glass substrate 10, and a plated layer 23 is formed on a top surface of the light-emitting element attaching portion 21. As a method of mounting the light-emitting element 51 on the light-emitting element attaching portion 21, the plating process can be exemplified, and as a method of mounting the driving semiconductor device 52 on the driving semiconductor device attaching portion 31, the reflow soldering process can be exemplified, but not limited thereto, and it is also possible to exemplify other methods, for example, the process using a solder ball or a solder bump. The second wiring portion 30 is further connected to a display apparatus drive circuit provided outside. Alternatively, in a case of forming a tiled display apparatus substrate or a display apparatus (light-emitting element display apparatus) formed by arraying the plurality of component-mounted glass wiring substrates (display apparatus substrates), the second wiring portion 30 is further connected to an adjacent component-mounted glass wiring substrate (display apparatus substrate) via, for example, a connector or an anisotropic conductive material.

One pixel includes the light-emitting element unit 50. In addition, the number of the plurality of light-emitting elements 51 connected to the one driving semiconductor device 52 can be, for example, three hundred. Note that FIG. 1 illustrates a state in which one light-emitting element 51 (51G) is connected to the one driving semiconductor device 52. In the display apparatus substrate of Example 1, one pixel (one pixel) includes, for example, a combination (the light-emitting element 50) including one red light-emitting element 51R, one green light-emitting element 51G, and one blue light-emitting element 51B. That is, N_{R}=N_{G}=N_{B}=1. The subpixel includes each light-emitting element 51. In addition, a plurality of light-emitting element units 50 is arrayed in a two-dimensional matrix form in a first direction and a second direction orthogonal to the first direction. As a size of one light-emitting element 51, specifically, 30 μm×30 μm can be exemplified, and as a size of the light-emitting element unit 50, specifically, 0.1 mm×0.1 mm can be exemplified, but not limited to these values.

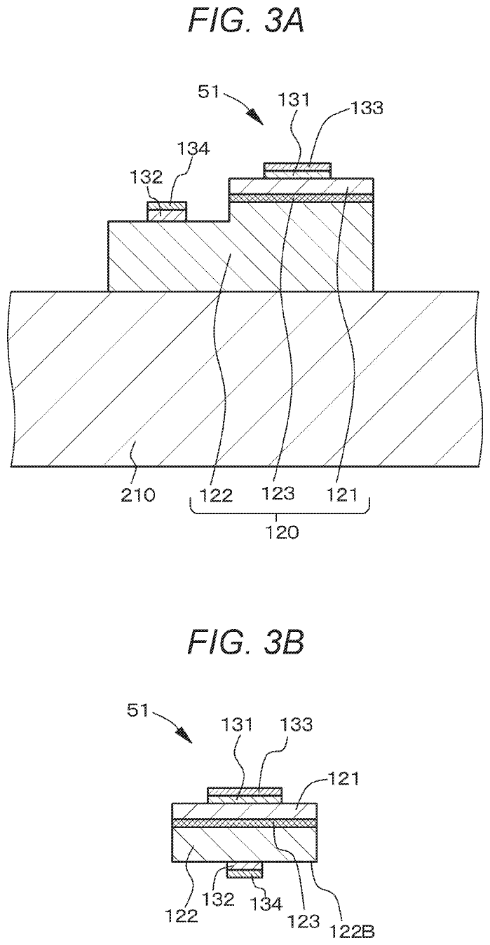

As illustrated in a schematic partial end surface view of FIG. 3A or 3B, the light-emitting element (specifically, the light-emitting diode) 51 includes a light-emitting layer 120, a first electrode 131, and a second electrode 132 electrically connected the light-emitting layer 120. Here, the light-emitting layer 120 has a laminated structure including a first compound semiconductor layer 121 having the first conductivity type (specifically, p-type), an active layer 123, and a second compound semiconductor layer 122 having the second conductivity type (specifically, n type) different from the first conductivity type. The light emitted from the active layer 123 is emitted to the outside through the second compound semiconductor layer 122. The light-emitting element 51 includes a red light-emitting element 51R, a green light-emitting element 51G, or a blue light-emitting element 51B. Specific configurations of the red light-emitting element 51R, the green light-emitting element 51G, and the blue light-emitting element 51B are, for example, as illustrated in Tables 1 and 2 below. Note that the light-emitting element illustrated in FIG. 3A differs from the light-emitting element illustrated in FIG. 3B in an arrangement position of the second electrode 132. Furthermore, a light-emitting element manufacturing substrate 210 described next is eventually removed.

That is, in the red light-emitting element 51R, the light-emitting layer (laminated structure) 120 including the second compound semiconductor layer 122 having the n-type conductivity type, the active layer 123, and the first compound semiconductor layer 121 having the p-type conductivity type includes an AlGaInP-based compound semiconductor. An n-GaAs substrate is used as the light-emitting element manufacturing substrate 210 to manufacture the red light-emitting element 51R. The second compound semiconductor layer 122 is formed on the light-emitting element manufacturing substrate 210. The active layer 123 has the multiple quantum well structure in which a well layer including a GaInP layer or an AlGaInP layer and a barrier layer including an AlGaInP layer having a different composition are laminated, and specifically, four barrier layers and three well layers are provided. In addition, the first electrode 131 is formed on a top surface of the first compound semiconductor layer 121, and a first pad portion 133 is formed on the first electrode 131. Furthermore, the second electrode 132 is formed on a top surface of the second compound semiconductor layer 122, and a second pad portion 134 is formed on the second electrode 132.

TABLE 1
Red light-emitting element 51R
First compound semiconductor layer

| | |
|---|---|
| Contact layer | p-GaAs: Zn-doped |
| Second clad layer | p-AlInP: Zn-doped |
| Second guide layer | AlGaInP |

Active layer

| | |
|---|---|
| Well layer/Barrier layer | GaInP/AlGaInP |

Second compound semiconductor layer

| | |
|---|---|
| First guide layer | AlGaInP |
| First clad layer | n-AlInP: Si-doped |

In the green light-emitting element 51G and the blue light-emitting element 51B, the light-emitting layer (laminated structure) 120 including the second compound semiconductor layer 122 having the n-type conductivity type, the active layer 123, and the first compound semiconductor layer 121 having the p-type conductivity type includes a GaInN-based compound semiconductor. An n-GaN substrate is used as the light-emitting element manufacturing substrate 210 in order to manufacture the green light-emitting element 51G and the blue light-emitting element 51B. The second compound semiconductor layer 122 is formed on the light-emitting element manufacturing substrate 210. The active layer 123 has a quantum well structure in which a well layer including an AlInGaN layer and a barrier layer including an AlInGaN layer having a different In composition are laminated, or alternatively, has a quantum well structure in which a well layer including an InGaN layer and a barrier layer including a GaN layer are laminated.

TABLE 2
Green light-emitting element 51G/Blue light-
emitting element 51B
First compound semiconductor layer

| | |
|---|---|
| Contact layer | p-GaN: Mg-doped |
| Second clad layer | p-AlGaN: Mg-doped |
| Second guide layer | InGaN |

Active layer

| | |
|---|---|
| Well layer/Barrier layer | InGaN/GaN |

Second compound semiconductor layer

| | |
|---|---|
| First guide layer | InGaN |
| First clad layer | n-AlGaN: Si-doped |

Hereinafter, a method of manufacturing the glass wiring substrate and a method of manufacturing the component-mounted glass wiring substrate of Example 1 will be described.

### [Step-100]

First, the glass substrate 10 including the first surface 10A and the second surface 10B facing the first surface 10A is prepared.

### [Step-110]

Then, the through hole 40 is formed in a desired region of the glass substrate 10. For example, drilling with a laser can be performed on the basis of a known technology. During the drilling with the laser, it is preferable that each of the first surface 10A and the second surface 10B be covered with a protective film that prevents glass scraps and the like generated during the drilling from adhering to the first surface 10A and the second surface 10B. Thereafter, it is preferable that the inner wall 41 of the through hole 40 be washed with hydrofluoric acid. Note that the through hole 40 can be formed by drilling, or the through hole 40 can be formed by adopting sandblasting. Alternatively, it is possible to adopt a combination of these machining methods and the etching process.

### [Step-120]

Subsequently, the first wiring is formed on the first surface 10A of the glass substrate 10, the second wiring is formed on the second surface 10B of the glass substrate 10, and additionally, the through hole portion 42 extending from the first wiring portion 20 and the second wiring portion 30, formed on the inner wall 41 of the through hole 40, and including the hollow portion 43 corresponding to the central portion of the through hole 40 is formed.

Specifically, a seed layer is formed on each of the first surface 10A and the second surface 10B including the inside of the through hole 40. The seed layer can be formed by, for example, the electroless copper plating process, or can be obtained by forming a seed layer including a Ti layer/Cu layer by the sputtering process. Then, by covering, with a plated resist layer, a region where copper plating should not be provided, and then applying the electrolytic copper plating thereto, the through hole portion 42 is formed from the inside of the through hole 40 over to the first wiring portion 20, and further the second wiring portion 30 extending from the through hole portion 42 is formed on the second surface 10B. Thereafter, the plated resist layer is removed, and soft etching is further applied to remove the seed layer. The first wiring portion 20 and the through hole portion 42 are integrally formed, and the second wiring portion 30 and the through hole portion 42 are integrally formed.

### [Step-130]

Thereafter, the filling member 61 that blocks at least a part of the through hole 40 is provided on the region 10C surrounding the edge portion of the through hole 40 of the first surface 10A. Specifically, for example, it is possible to provide the filling member 61 that blocks at least a part of the through hole 40 by using a 3D printer and arranging the filling member 61 including a molten glass material on the region 10C surrounding the edge portion of the through hole 40 of the first surface 10A (by applying a kind of potting).

### [Step-140]

Subsequently, the electronic components (the light-emitting element 51 and the driving semiconductor device 52) are mounted on the first wiring portion 20 and the second wiring portion 30. Thus, the structure illustrated in FIG. 1 can be obtained.

Specifically, the insulation layer 22 is formed on the first surface 10A of the glass substrate 10, an opening is provided in a portion of the insulation layer 22 located above the first wiring portion 20, a conductive material layer is formed on the insulation layer 22 including the inside of the opening, and subsequently, the conductive material layer is patterned, thereby forming the light-emitting element attaching portion 21 extending from the first wiring portion 20.

Then, a region of the first surface 10A of the glass substrate 10 (specifically, on the insulation layer 22) where the electronic component (light-emitting element 51) should be mounted and the first wiring portion 20 (specifically, the light-emitting element attaching portion 21) is not formed is coated with a thermosetting adhesive. Then, the thermosetting adhesive is thermally cured after the light-emitting element 51 is placed on the thermosetting adhesive, and the light-emitting element 51 is fixed to the first surface 10A of the glass substrate 10 (specifically, onto the insulation layer 22). Subsequently, the first wiring portion 20 and the light-emitting elements 51 are connected by the plated layer 23 on the basis of the electrolytic copper plating process. Specifically, the first electrode 131 (more specifically, the first pad portion 133) and the second electrode 132 (more specifically, the second pad portion 134) of the light-emitting element 51 are connected to the light-emitting element attaching portion 21 by the plated layer 23 on the basis of the electrolytic copper plating process. It is only to form a resist mask layer in advance, as necessary, in a region where the plated layer 23 should not be formed.

Alternatively, the first surface 10A of the glass substrate (specifically, onto the insulation layer 22 including the top of the light-emitting element attaching portion 21) is coated with an ultraviolet curable adhesive layer. Then, the ultraviolet curable adhesive is cured by irradiating the second surface side of the glass substrate 10 with ultraviolet after the light-emitting element 51 is placed on the ultraviolet curable adhesive, and the light-emitting element 51 is fixed to the first surface 10A of the glass substrate 10 (specifically, the light-emitting element attaching portion 21). Subsequently, the ultraviolet curable adhesive that has not been cured is removed, and then, the first wiring portion 20 and the light-emitting element 51 are connected by the plated layer 23 on the basis of the electrolytic copper plating process. Specifically, the first electrode 131 (more specifically, the first pad portion 133) and the second electrode 132 (more specifically, the second pad portion 134) of the light-emitting element 51 are connected to the light-emitting element attaching portion 21 by the plated layer 23 on the basis of the electrolytic copper plating process. It is only to form the resist mask layer in advance, as necessary, in the region where the plated layer 23 should not be formed. Note that the cured ultraviolet curable adhesive may be removed thereafter.

Thereafter, the attaching terminal portion 53 of the driving semiconductor device 52 is mounted on the driving semiconductor device attaching portion 31 on the basis of the reflow soldering process.

Steps of mounting the light-emitting element 51 on the first wiring portion 20 will be described below.

### [Step-200]

First, an underlayer, the second compound semiconductor layer 122, the active layer 123, and the first compound semiconductor layer 121 are formed on the light-emitting element manufacturing substrate 210 by a known method, and then patterning is applied after the first electrode 131 is formed on the first compound semiconductor layer 121 by a known method. Furthermore, the second electrode 132 is formed, although depending on a structure of the light-emitting element. Thus, a product in process of the light-emitting element illustrated in FIG. 3A can be obtained. Hereinafter, the “product in process of the light-emitting element” will be referred to as a “light-emitting element 200” for convenience.

### [Step-210]

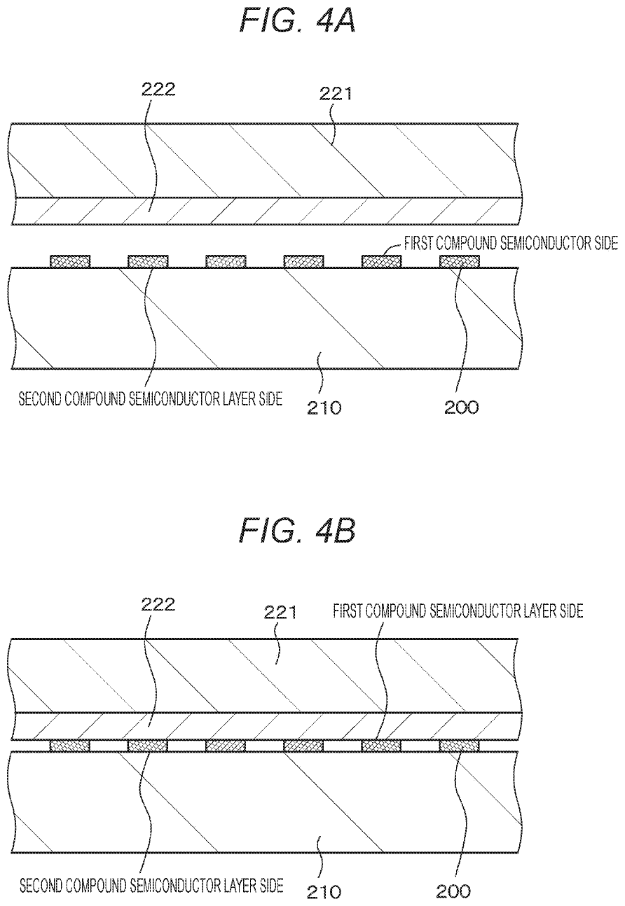

Next, the light-emitting element is temporarily fixed to a first temporary fixing substrate 221 via the first electrode 131. Specifically, the first temporary fixing substrate 221 including a glass substrate is prepared, in which the glass substrate has a surface on which an adhesion layer 222 including an uncured adhesive is formed. Then, the light-emitting element 200 can be temporarily fixed to the first temporary fixing substrate 221 by bonding the light-emitting element 200 to the adhesion layer 222 and curing the adhesion layer 222 (see FIGS. 4A and 4B).

### [Step-220]

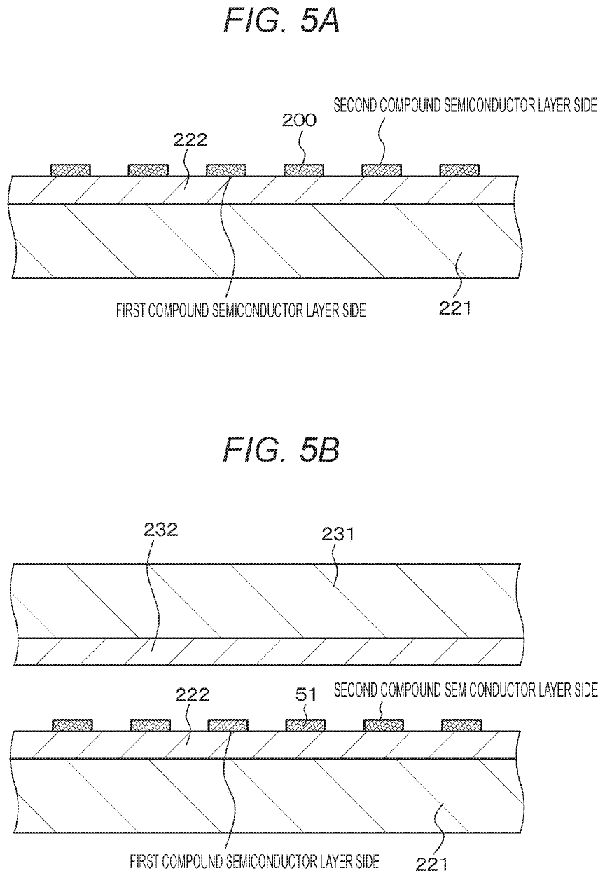

Thereafter, the light-emitting element 200 is separated from the light-emitting element manufacturing substrate 210 (see FIG. 5A). Specifically, the light-emitting element manufacturing substrate 210 is removed and thereby the second compound semiconductor layer 122 can be exposed by lapping the light-emitting element manufacturing substrate 210 from a back surface thereof to make it thin, and subsequently, by applying wet-etching to the light-emitting element manufacturing substrate 210 and the underlayer.

Note that examples of a material constituting the first temporary fixing substrate 221 can include a metal plate, an alloy plate, a ceramics plate, and a plastic plate in addition to the glass substrate. Examples of the method of temporarily fixing the light-emitting element to the first temporary fixing substrate 221 can include a metal joining process, a semiconductor joining process, and a metal/semiconductor joining process in addition to the method using the adhesive. Furthermore, exemplary methods of removing the light-emitting element manufacturing substrate 210 and the like from the light-emitting element can include a laser ablation process and a heating process in addition to the etching process.

### [Step-230]

Next, the second electrode 132 is formed on a light-emitting surface 122B of the exposed second compound semiconductor layer 122 by a so-called lift-off process, although depending on the structure of the light-emitting element. Thus, the light-emitting element 51 can be obtained.

### [Step-240]

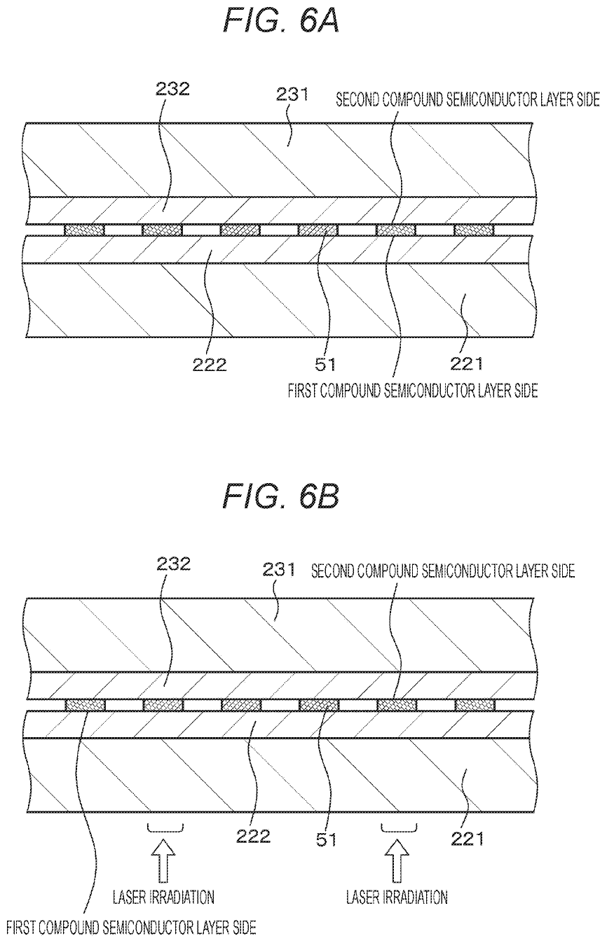

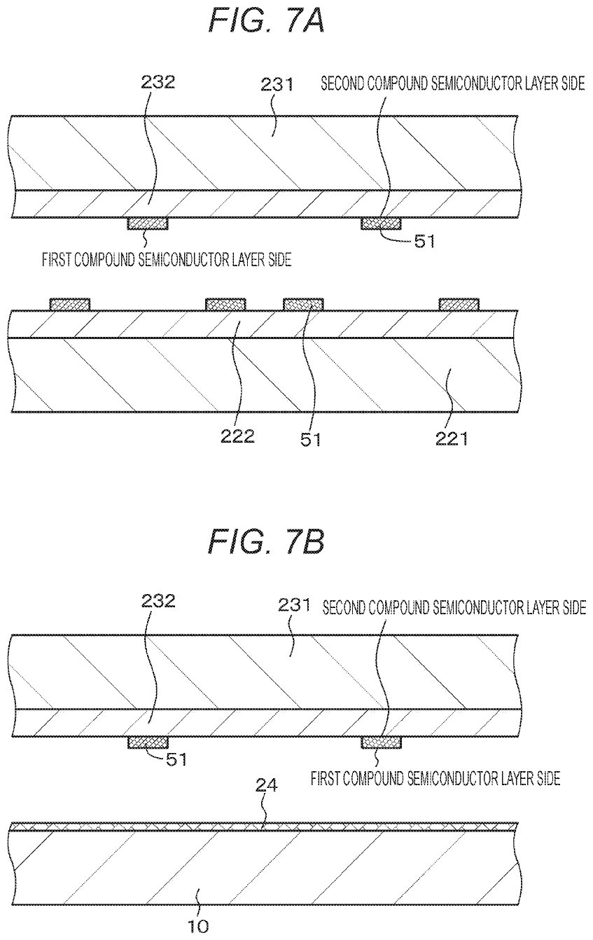

A second temporary fixing substrate 231 on which a slightly-adhesive layer 232 including silicone rubber is formed is prepared. Then, the slightly-adhesive layer 232 is pressed against the light-emitting elements 51 on the first temporary fixing substrate 221 where light-emitting elements 51 remain in an array form (two-dimensional matrix form) (see FIGS. 5B and 6A). Examples of a material constituting the second temporary fixing substrate 231 can include a glass plate, a metal plate, an alloy plate, a ceramics plate, a semiconductor substrate, and a plastic plate. Furthermore, the second temporary fixing substrate 231 is held by a positioning device not illustrated. A positional relation between the second temporary fixing substrate 231 and the first temporary fixing substrate 221 can be adjusted by operating the positioning device. Subsequently, the light-emitting elements 51 to be mounted (to be attached to the glass substrate 10) are irradiated by, for example, an excimer laser from a back surface side of the first temporary fixing substrate 221 (see FIG. 6B). Consequently, laser ablation is caused and the light-emitting elements 51 irradiated by the excimer laser are separated from the first temporary fixing substrate 221. Thereafter, when contact between the second temporary fixing substrate 231 and the light-emitting elements 51 is released, the light-emitting elements 51 separated from the first temporary fixing substrate 221 are each brought into a state of adhering to the slightly-adhesive layer 232 (see FIG. 7A).

Subsequently, the light-emitting elements 51 are arranged (moved or transferred) onto the thermosetting adhesive or the ultraviolet curable adhesive layer (hereinafter, referred to as an “adhesive layer 24”) described in [step-140] (see FIG. 7B). Note that the glass substrate 10 illustrated in FIG. 7B more simply illustrates the configuration and the structure of the glass substrate 10 illustrated in FIG. 1.

Thereafter, it is only required to execute [step-140] of Example 1. Specifically, the light-emitting elements 51 are arranged from the second temporary fixing substrate 231 on the adhesive layer 24 with which the first surface side of the glass substrate 10 is coated, while using an alignment mark formed on the first surface 10A of the glass substrate 10 as a reference. Since the light-emitting elements 51 lightly adhere to the slightly-adhesive layer 232, when the second temporary fixing substrate 231 is moved in a direction away from the glass substrate 10 in a state where the light-emitting elements 51 are in contact with (pressed against) the adhesive layer 24, the light-emitting elements 51 are made to remain on the adhesive layer 24. Furthermore, as necessary, the light-emitting elements 51 can be attached to the first surface 10A of the glass substrate 10 by deeply embedding the light-emitting elements 51 in the adhesive layer 24 with a roller or the like.

A method using such a second temporary fixing substrate 231 will be referred to as a step transfer process for convenience. Then, the desired number of light-emitting elements 51 adhere to the slightly-adhesive layer 232 in the two-dimensional matrix and are transferred onto the glass substrate 10 by repeating such a step transfer process the desired number of times. Specifically, for example, in one-time step transfer, 160×120 light-emitting elements 51 are made to adhere to the slightly-adhesive layer 232 in the two-dimensional matrix form and are transferred onto the glass substrate 10. Therefore, 1920×1080 light-emitting elements 51 can be transferred onto the glass substrate 10 by repeating the step transfer process (1920×1080)/(160×120)=108 times. Then, the predetermined number of red light-emitting elements 51R, the predetermined number of green light-emitting elements 51G, and the predetermined number of blue light-emitting elements 51B can be attached at predetermined intervals and pitches to the glass substrate 10 by repeating the above-described steps three times in total.

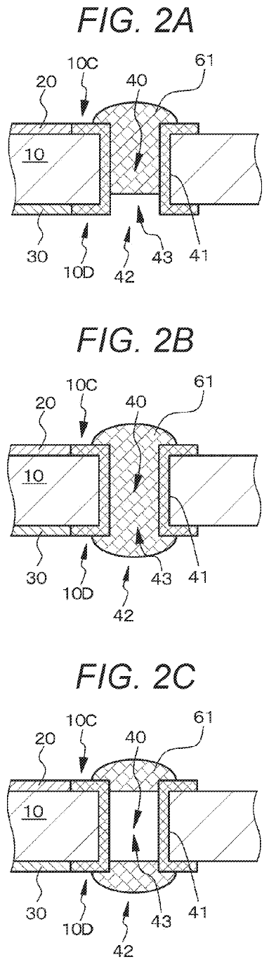

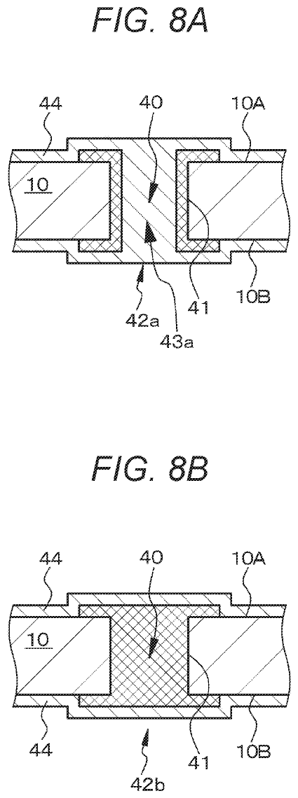

Various simulations were performed while setting the thickness of the glass substrate 10 to 0.5 mm and a diameter of the through hole 40 to 0.14 mm. The through hole portion 42 was formed on the inner wall 41 of the through hole 40 on the basis of the copper plating process, and the hollow portion 43 was formed in the through hole portion 42 (see FIG. 2B as described later), and such a state is defined as Example 2A. Note that an outer diameter of the filling member 61 (see FIG. 2B) on the first surface 10A and the second surface 10B of the glass substrate 10 was 0.4 mm. Furthermore, a through hole portion 42a was formed on the inner wall 41 of the through hole 40 on the basis of the copper plating, a hollow portion 43a was formed in the through hole portion 42a, and the hollow portion 43a was filled with a solder resist material 44 (see FIG. 8A), and such a state was defined as Comparative Example 1A. Moreover, a through hole portion 42b was formed by filling the inside of the through hole 40 completely with copper on the basis of copper plating (see FIG. 8B), and such a state was defined as Comparative Example 1B. Note that, in Example 2A and Comparative Example 1A, a thickness of a copper plated layer on the surface of the glass substrate 10 was set to 3 μm. In Example 2A, Comparative Example 1A, and Comparative Example 1B, the wiring portions 20 and 30 were not formed.

Then, in each of Example 2A, Comparative Example 1A, and Comparative Example 1B, maximum stress (referred to as “maximum stress-A” for convenience) generated in the glass substrate at the time of exposure to a temperature of 260° C. for 5 seconds was calculated through the simulations. Results thereof are provided in Table 3 below. Furthermore, a first ring made of metal and having an outer diameter of 3.5 mm and an inner diameter of 2.5 mm (however, note that a contact portion with a sample is a round-shaped edge-like portion having a diameter of 3.0 mm) and a second ring made of metal and having an outer diameter of 6.5 mm and an inner diameter of 5.5 mm (however, note that a contact portion with the sample is a round-shaped edge-like portion having a diameter of 6.0 mm) were assumed, and maximum stress (referred to as “maximum stress-B”) generated in the glass substrate at the time of applying a predetermined load to the first ring was calculated in a state in which the first ring was arranged on the upper side, the second ring was arranged on the lower side, and the simulation object in each of Example 2A, Comparative Example 1A, Comparative Example 1B is sandwiched between the first ring and the second ring while holding the second ring. Results thereof are provided in Table 4 below.

TABLE 3

| | Maximum stress-A (MPa) |
|---|---|
| Example 2A | 28 |
| Comparative Example 1A | 251 |
| Comparative Example 1B | 342 |

TABLE 4

| | Maximum stress-B (MPa) |
|---|---|
| Example 2A | 33 |
| Comparative Example 1A | 212 |
| Comparative Example 1B | 162 |

It is understood from the results of Table 3 that the maximum stress-A generated in the glass substrate can be extremely lowered by providing the filling member 61 even though the heat is applied to the glass substrate. Furthermore, it is understood from the results of Table 4 that the maximum stress-B generated in the glass substrate is extremely low by providing the filling member 61 even when the load is applied to the glass substrate.

In the glass wiring substrate of Example 1 or Example 2 as described later or the component-mounted glass wiring substrate of the present disclosure, the filling member includes the glass material, and therefore, no large stress is applied to the glass substrate even in the case where the load is applied to the glass substrate, or no large stress is applied to the glass substrate even in the case where the heat is applied to the glass substrate, and a problem like damaging the glass substrate can be prevented. Furthermore, since the relation between the linear expansion coefficient CTE₁ of the glass substrate and the linear expansion coefficient CTE₂ of the filling member is prescribed, even in the case where the glass substrate is heated to two hundred and several tens of degrees Celsius in the manufacturing steps, stress caused by a difference between the linear expansion coefficient of the glass substrate and the linear expansion coefficient of the material constituting the first wiring portion and the second wiring portion is unlikely to be applied to the glass substrate, and as a result thereof, the problem like damaging the glass substrate can be prevented.

### EXAMPLE 2

Example 2 is modification of Example 1. As illustrated in the schematic partial end surface view of a vicinity of the through hole portion in the glass wiring substrate, the component-mounted glass wiring substrate, and the display apparatus substrate in FIG. 2A, the filling member 61 extends through the inside of the through hole 40 in the glass wiring substrate of Example 2.

Alternatively, as illustrated in the schematic partial end surface view of the vicinity of the through hole portion in the glass wiring substrate, the component-mounted glass wiring substrate, and the display apparatus substrate in FIG. 2B, the filling member 61 extends from the inside of the through hole 40 onto the region 10D surrounding the edge portion of the through hole 40 of the second surface 10B in a modified example of Example 2.

Alternatively, as illustrated in the schematic partial end surface view of the vicinity of the through hole portion in the glass wiring substrate, the component-mounted glass wiring substrate, and the display apparatus substrate in FIG. 2C, a second filling member 62 which includes a glass material and blocks the through hole 40 is provided on the region 10D surrounding the edge portion of the through hole 40 of the second surface 10B in another modified example of Example 2. Inside the through hole 40, a space may exist between an end portion of the filling member 61 and an end portion of the second filling member 62, or the end portion of the filling member 61 may contact the end portion of the second filling member 62.

Except for the above-described points, the glass wiring substrate, the component-mounted glass wiring substrate, and the display apparatus substrate in Example 2 can have the configurations and the structures similar to those of the glass wiring substrate, the component-mounted glass wiring substrate, and the display apparatus substrate in Example 1, and therefore, detailed description thereof will be omitted.

In the above, the description has been provided on the basis of the preferable Examples of the present disclosure, but the present disclosure is not limited to such Examples. The configurations and structures of the glass wiring substrate, the component-mounted glass wiring substrate, the display apparatus substrate, and the light-emitting elements described in Examples are examples, and the members, the materials, and the like constituting these are also examples and may be changed as appropriate. Furthermore, the method of manufacturing the glass wiring substrate and the method of manufacturing the component-mounted glass wiring substrate are also examples and can be changed as appropriate. For example, the lamination order of the compound semiconductor layers in a light-emitting element may be reversed.

A protective layer may also be formed on an entire surface on the first surface side of the glass substrate 10. Furthermore, a light absorption layer may be formed on the protective layer except for a portion of the protective layer from which light is emitted from the light-emitting elements.

Note that the present disclosure can also adopt the following configurations.

### [A01] <<Glass Wiring Substrate: First Aspect>>

A glass wiring substrate including:

a glass substrate including a first surface and a second surface facing the first surface, having a first wiring portion formed on a first surface side, and having a second wiring portion formed on a second surface side;

a through hole formed in a region of the glass substrate in which neither the first wiring portion nor the second wiring portion is formed; and

a through hole portion formed on an inner wall of the through hole, having one end extending to the first wiring portion, having another end extending to the second wiring portion, and including a hollow portion corresponding to a central portion of the through hole, in which

a filling member that blocks at least a part of the through hole is provided on a region surrounding an edge portion of the through hole of the first surface, and

the filling member includes a glass material.
[A02] The glass wiring substrate according to [A01], in which the filling member extends through an inside of the through hole.
[A03] The glass wiring substrate according to [A02], in which the filling member extends from the inside of the through hole onto a region surrounding an edge portion of the through hole of the second surface.
[A04] The glass wiring substrate according to [A01], in which a second filling member including a glass material and blocking the through hole is provided on a region surrounding an edge portion of the through hole of the second surface.
[A05] The glass wiring substrate according to any one of [A01] to [A04], in which when a linear expansion coefficient of the glass substrate is defined as CTE₁ and a linear expansion coefficient of the filling member is defined as CTE₂,

0.01≤CTE₂/CTE₁≤5

is satisfied.
[A06] The glass wiring substrate according to any one of [A01] to [A05], in which

when a Young's modulus of the glass substrate is defined as E₁ and a Young's modulus of the filling member is defined as E₂,

0.1≤E₂/E₁≤10

is satisfied.

### [A07] <<Glass Wiring Substrate: Second Aspect>>

A glass wiring substrate including:

a glass substrate including a first surface and a second surface facing the first surface, having a first wiring portion formed on a first surface side, and having a second wiring portion formed on a second surface side;

a through hole formed in a region of the glass substrate in which neither the first wiring portion nor the second wiring portion is formed; and

a through hole portion formed on an inner wall of the through hole, having one end extending to the first wiring portion, having another end extending to the second wiring portion, and including a hollow portion corresponding to a central portion of the through hole, in which

a filling member that blocks at least a part of the through hole is provided on a region surrounding an edge portion of the through hole of the first surface, and

when a linear expansion coefficient of the glass substrate is defined as CTE₁ and a linear expansion coefficient of the filling member is defined as CTE₂,

0.01≤CTE₂/CTE₁≤5

is satisfied.
[A08] The glass wiring substrate according to [A07], in which the filling member extends through an inside of the through hole.
[A09] The glass wiring substrate according to [A08], in which the filling member extends from the inside of the through hole onto a region surrounding an edge portion of the through hole of the second surface.
[A10] The glass wiring substrate according to [A07], in which a second filling member including a glass material and blocking the through hole is provided on a region surrounding an edge portion of the through hole of the second surface.
[A11] The glass wiring substrate according to any one of [A07] to [A10], in which

when a Young's modulus of the glass substrate is defined as E₁ and a Young's modulus of the filling member is defined as E₂,

0.1≤E₂/E₁≤10

is satisfied.

### [B01] <<Component-Mounted Glass Wiring Substrate>>

A component-mounted glass wiring substrate including:

a glass substrate including a first surface and a second surface facing the first surface, having a first wiring portion formed on a first surface side, and having a second wiring portion formed on a second surface side;

a through hole formed in a region of the glass substrate in which neither the first wiring portion nor the second wiring portion is formed;

a through hole portion formed on an inner wall of the through hole, having one end extending to the first wiring portion, having another end extending to the second wiring portion, and including a hollow portion corresponding to a central portion of the through hole; and

an electronic component mounted on at least one of the first wiring portion or the second wiring portion, in which

a filling member that blocks at least a part of the through hole is provided on a region surrounding an edge portion of the through hole of the first surface, and

the filling member includes a glass material.
[B02] The component-mounted glass wiring substrate according to [B01], in which

the electronic component includes a light-emitting element and a driving semiconductor device that drives the light-emitting element,

the light-emitting element is mounted on one wiring portion of the first wiring portion or the second wiring portion, and

the driving semiconductor device is mounted on another wiring portion of the first wiring portion or the second wiring portion.

### [C01] <<Display Apparatus Substrate>>

A display apparatus substrate including:

a glass substrate including a first surface and a second surface facing the first surface, having a first wiring portion formed on a first surface side, and having a second wiring portion formed on a second surface side;

a through hole formed in a region of the glass substrate in which neither the first wiring portion nor the second wiring portion is formed;

a through hole portion formed on an inner wall of the through hole, having one end extending to the first wiring portion, having another end extending to the second wiring portion, and including a hollow portion corresponding to a central portion of the through hole; and

an electronic component mounted on at least one of the first wiring portion or the second wiring portion, in which

the electronic component includes at least a light-emitting element, and

a filling member that blocks at least a part of the through hole is provided on a region surrounding an edge portion of the through hole of the first surface.
[C02] The display apparatus substrate according to [C01], in which

the electronic component includes a light-emitting element and a driving semiconductor device that drives the light-emitting element,

the light-emitting element is mounted on a light-emitting element attaching portion provided in one wiring portion of the first wiring portion or the second wiring portion, and

the driving semiconductor device is mounted on a driving semiconductor device attaching portion provided in another wiring portion of the first wiring portion or the second wiring portion.

### [C03] <<Tiled Display Apparatus Substrate>>

A tiled display apparatus substrate formed by arraying a plurality of the component-mounted glass wiring substrates according to [B01] or [B02] or the display apparatus substrates according to [C01] or [B02].

### [D01] <<Method of Manufacturing Glass Wiring Substrate>>

A method of manufacturing a glass wiring substrate, including respective steps of:

preparing a glass substrate including a first surface and a second surface facing the first surface;

forming a through hole in a desired region of the glass substrate;

subsequently, forming first wiring on the first surface of the glass substrate, forming second wiring on the second surface of the glass substrate, forming a through hole portion extending from a first wiring portion and a second wiring portion, formed on an inner wall of the through hole, and including a hollow portion corresponding to a central portion of the through hole; and thereafter

providing, on a region surrounding an edge portion of the through hole of the first surface, a filling member that blocks at least a part of the through hole, in which

the filling member includes a glass material, or

when a linear expansion coefficient of the glass substrate is defined as CTE₁ and a linear expansion coefficient of the filling member is defined as CTE₂,

0.01≤CTE₂/CTE₁≤5

is satisfied.

### REFERENCE SIGNS LIST

10 Glass substrate
10A First surface of glass substrate
10B Second surface of glass substrate
20 First wiring portion
21 Light-emitting element attaching portion
22 Insulation layer
23 Plated layer
24 Adhesive layer
30 Second wiring portion
31 Driving semiconductor device attaching portion
40 Through hole
41 Inner wall of through hole
42 Through hole portion
43 Hollow portion
44 Solder resist material
50 Light-emitting element unit
51,51R, 51G, 51B Electronic component (light-emitting element)
52 Driving semiconductor device
53 Attaching terminal portion
61 Filling member
62 Second filling member
120 Light-emitting layer
121 First compound semiconductor layer
122 Second compound semiconductor layer
122B Light-emitting surface
123 Active layer
131 First electrode
132 Second Electrode
133,134 Pad portion
200 Light-emitting element
210 Light-emitting element manufacturing substrate
221 First temporary fixing substrate
222 Adhesion layer
231 Second temporary fixing substrate
232 Slightly-adhesive layer

1. A glass wiring substrate comprising:
a glass substrate including a first surface and a second surface facing the first surface, having a first wiring portion formed on a first surface side, and having a second wiring portion formed on a second surface side;
a through hole formed in a region of the glass substrate in which neither the first wiring portion nor the second wiring portion is formed; and
a through hole portion formed on an inner wall of the through hole, having one end extending to the first wiring portion, having another end extending to the second wiring portion, and including a hollow portion corresponding to a central portion of the through hole, wherein
a filling member that blocks at least a part of the through hole is provided on a region surrounding an edge portion of the through hole of the first surface, and
the filling member includes a glass material.

2. The glass wiring substrate according to claim 1, wherein the filling member extends through an inside of the through hole.

3. The glass wiring substrate according to claim 2, wherein the filling member extends from the inside of the through hole onto a region surrounding an edge portion of the through hole of the second surface.

4. The glass wiring substrate according to claim 1, wherein a second filling member including a glass material and blocking the through hole is provided on a region surrounding an edge portion of the through hole of the second surface.

5. The glass wiring substrate according to claim 1, wherein
when a linear expansion coefficient of the glass substrate is defined as CTE₁ and a linear expansion coefficient of the filling member is defined as CTE₂,
0.01≤CTE₂/CTE₁≤5
is satisfied.

6. The glass wiring substrate according to claim 1, wherein
when a Young's modulus of the glass substrate is defined as E₁ and a Young's modulus of the filling member is defined as E₂,
0.1≤E₂/E₁≤10
is satisfied.

7. A glass wiring substrate comprising:
a glass substrate including a first surface and a second surface facing the first surface, having a first wiring portion formed on a first surface side, and having a second wiring portion formed on a second surface side;
a through hole formed in a region of the glass substrate in which neither the first wiring portion nor the second wiring portion is formed; and
a through hole portion formed on an inner wall of the through hole, having one end extending to the first wiring portion, having another end extending to the second wiring portion, and including a hollow portion corresponding to a central portion of the through hole, wherein
a filling member that blocks at least a part of the through hole is provided on a region surrounding an edge portion of the through hole of the first surface, and
when a linear expansion coefficient of the glass substrate is defined as CTE₁ and a linear expansion coefficient of the filling member is defined as CTE₂,
0.01≤CTE₂/CTE₁≤5
is satisfied.

8. The glass wiring substrate according to claim 7, wherein the filling member extends through an inside of the through hole.

9. The glass wiring substrate according to claim 8, wherein the filling member extends from the inside of the through hole onto a region surrounding an edge portion of the through hole of the second surface.

10. The glass wiring substrate according to claim 7, wherein a second filling member including a glass material and blocking the through hole is provided on a region surrounding an edge portion of the through hole of the second surface.

11. The glass wiring substrate according to claim 7, wherein
when a Young's modulus of the glass substrate is defined as E₁ and a Young's modulus of the filling member is defined as E₂,
0.1≤E₂/E₁≤10
is satisfied.

12. A component-mounted glass wiring substrate comprising:
a glass substrate including a first surface and a second surface facing the first surface, having a first wiring portion formed on a first surface side, and having a second wiring portion formed on a second surface side;
a through hole formed in a region of the glass substrate in which neither the first wiring portion nor the second wiring portion is formed;
a through hole portion formed on an inner wall of the through hole, having one end extending to the first wiring portion, having another end extending to the second wiring portion, and including a hollow portion corresponding to a central portion of the through hole; and
an electronic component mounted on at least one of the first wiring portion or the second wiring portion, wherein
a filling member that blocks at least a part of the through hole is provided on a region surrounding an edge portion of the through hole of the first surface, and
the filling member includes a glass material.

13. The component-mounted glass wiring substrate according to claim 12, wherein
the electronic component includes a light-emitting element and a driving semiconductor device that drives the light-emitting element,
the light-emitting element is mounted on one wiring portion of the first wiring portion or the second wiring portion, and
the driving semiconductor device is mounted on another wiring portion of the first wiring portion or the second wiring portion.
